(19) United States
(12) Patent Application Publication
(10) Pub. No.: US 2024/0055571 A1
(43) Pub. Date: Feb. 15, 2024

(54) ELECTRONIC DEVICE

(71) Applicants: Innolux Corporation, Miaoli County (TW); CARUX TECHNOLOGY PTE. LTD., SINGAPORE (SG)

(72) Inventors: Yu-Chia Huang, Miaoli County (TW); Yuan-Lin Wu, Miaoli County (TW); Yu-Ling Hung, SINGAPORE (SG); Tsung-Han Tsai, Miaoli County (TW); Kuan-Feng Lee, Miaoli County (TW)

(73) Assignees: Innolux Corporation, Miaoli County (TW); CARUX TECHNOLOGY PTE. LTD., SINGAPORE (SG)

(21) Appl. No.: 18/347,583

(22) Filed: Jul. 6, 2023

(30) Foreign Application Priority Data
Aug. 11, 2022 (CN) 202210963465.1

(51) Int. Cl. H01L 33/62; H01L 33/58

(52) U.S. Cl. CPC H01L 33/62; H01L 33/58; B32B 2457/20

(57) ABSTRACT

An electronic device is disclosed. The electronic device includes a first substrate, a circuit assembly, a second substrate, a first adhesive layer, and a second adhesive layer. The circuit assembly is disposed on the first substrate. The second substrate is disposed on the circuit assembly. The first adhesive layer is disposed between the circuit assembly and the first substrate. The first adhesive layer has a first outer profile. The second adhesive layer is disposed between the circuit assembly and the second substrate. The second adhesive layer has a second outer profile. The first outer profile and the second outer profile correspond to a same side of the electronic device. At least a portion of the first outer profile and at least a portion of the second outer profile are non-overlapped.

### CROSS-REFERENCE TO RELATED APPLICATION

This application claims the priority benefit of Chinese application no. 202210963465.1, filed on Aug. 11, 2022. The entirety of the above-mentioned patent application is hereby incorporated by reference herein and made a part of this specification.

### BACKGROUND

### Technical Field

The disclosure relates to an electronic device. Particularly, the disclosure relates to an electronic device that facilitates distinguishing front and back sides during assembling or reduces errors in assembling.

### Description of Related Art

Electronic devices or tiled electronic devices have been widely applied to different fields such as communication, display, vehicle, aviation, or the like. The vigorous progressing electronic devices are developed toward lightweighting and thinning. Therefore, requirements for the reliability or quality of the electronic devices are increasing.

### SUMMARY

The disclosure provides an electronic device that facilitates distinguishing front and back sides during assembling or reduces errors in assembling.

According to an embodiment of the disclosure, an electronic device includes a first substrate, a circuit assembly, a second substrate, a first adhesive layer, and a second adhesive layer. The circuit assembly is disposed on the first substrate. The second substrate is disposed on the circuit assembly. The first adhesive layer is disposed between the circuit assembly and the first substrate. The first adhesive layer has a first outer profile. The second adhesive layer is disposed between the circuit assembly and the second substrate. The second adhesive layer has a second outer profile. The first outer profile and the second outer profile correspond to a same side of the electronic device. At least a portion of the first outer profile and at least a portion of the second outer profile are non-overlapped.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of an electronic device according to an embodiment of the disclosure.

FIG. 2 is a schematic cross-sectional view of the electronic device of FIG. 1 along section line I-I′.

FIG. 3 is a schematic top view of an electronic device according to another embodiment of the disclosure.

FIG. 4 is a schematic cross-sectional view of the electronic device of FIG. 3 along section line II-II′.

FIG. 5 is a schematic top view of an electronic device according to another embodiment of the disclosure.

FIG. 6 is a schematic cross-sectional view of the electronic device of FIG. 5 along section line III-III′.

FIG. 7 is a schematic top view of an electronic device according to another embodiment of the disclosure.

FIG. 8 is a schematic side view of the electronic device of FIG. 7.

FIG. 9 is a schematic top view of an electronic device according to another embodiment of the disclosure.

FIG. 10 is a schematic side view of the electronic device of FIG. 9.

FIG. 11 is a schematic cross-sectional view of an electronic device according to another embodiment of the disclosure.

FIG. 12 is a schematic top view of an electronic device according to another embodiment of the disclosure.

FIG. 13 is a schematic cross-sectional view of the electronic device of FIG. 12 along section line IV-IV′.

### DESCRIPTION OF THE EMBODIMENTS

The disclosure may be understood with reference to the following detailed description together with the accompanying drawings. It should be noted that, for ease of understanding by readers and clarity of the drawings, a plurality of drawings in the disclosure merely show a part of an electronic device, and specific elements in the drawings are not drawn to scale. In addition, the number and size of elements in the drawings only serve for exemplifying instead of limiting the scope of the disclosure.

In following description and claims, terms such as “include”, “comprise”, and “have” are open-ended terms, and thus should be interpreted as “including, but not limited to”.

The directional terms mentioned herein, like “above”, “below”, “front”, “back”, “left”, “right”, and the like, refer only to the directions in the accompanying drawings. Therefore, the directional terms are used for describing instead of limiting the disclosure.

It should be understood that when an element or film layer is referred to as being “on”, or “connected to” another element or film layer, the element or film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between.

Although terms such as “first”, “second”, “third”, etc. may be used to describe diverse constituent elements, such constituent elements are not limited by the terms. The terms are used only to discriminate one constituent element from other constituent elements in the specification. Instead of using the same terms in the claims, the terms first, second, third, etc. may be used in accordance with the order of claiming an element. Accordingly, in the following description, a first constituent element may be a second constituent element in the claims.

Herein, the term “about”, “approximately”, “substantially”, or “essentially” typically represents that a value is within 10%, 5%, 3%, 2%, 1%, or 0.5% of a given value or range. Herein, the given value is an approximate value, namely implicitly meaning “about,” “approximately”, “substantially”, or “essentially” without specifically describing the terms “about,” “approximately”, “substantially”, or “essentially”.

In some embodiments of the disclosure, terms related to bonding and connection such as “connection”, “interconnection”, etc., unless specifically defined, may indicate the case where two structures are in direct contact, or where two structures are not in direct contact and other structures are disposed in between. Moreover, such terms related to bonding and connection may also cover the case where two structures are both movable or where two structures are both fixed. In addition, the term “couple” includes any direct and indirect electrical connection means.

In some embodiments of the disclosure, an optical microscopy (OM), a scanning electron microscope (SEM), a thin film thickness profiler (α-step), an ellipsometer, or other suitable manner may be used to measure an area, a width, a thickness, or a height of each element or measure a distance or a spacing between elements. To be specific, according to some embodiments, a SEM may be used to obtain a cross-sectional structural image including an element to be measured, and measure an area, a width, a thickness, or a height of each element or measure a distance or a spacing between elements.

In the disclosure, the electronic device may include, for example but not limited to, a display device, an antenna device, a transparent display device, a transparency adjustment device, a heating device, a sensing device, or a tiled device. The electronic device may include a bendable or flexible electronic device. The display device may include a liquid crystal or a light-emitting diode (LED), for example. The light-emitting diode may include an organic light-emitting diode (OLED), a mini LED, a micro LED, a quantum dot LED (e.g., QLED or QDLED), fluorescence, phosphor, or other suitable materials or any arrangement or combination of the materials, for example but not limited thereto. The antenna device may be a liquid crystal antenna or an electronic-component antenna, for example but not limited thereto. The tiled device may be a tiled display device or a tiled antenna device, for example but not limited thereto. It should be noted that the electronic device may be any arrangement or combination of the foregoing, but not limited thereto. Hereinafter, an electronic device will be taken to describe the disclosure, but the disclosure is not limited thereto.

It should be understood that the features in several different embodiments below may be replaced, recombined, or mixed with each other to form other embodiments without departing from the spirit of the disclosure. The features in the embodiments may be arbitrarily used in mixture or combination without departing from the spirit of the disclosure or conflicting with each other.

Reference will now be made in detail to the exemplary embodiments of the disclosure, examples of which are illustrated in the accompanying drawings. Wherever possible, the same reference numerals are used in the drawings and description to refer to the same or like parts.

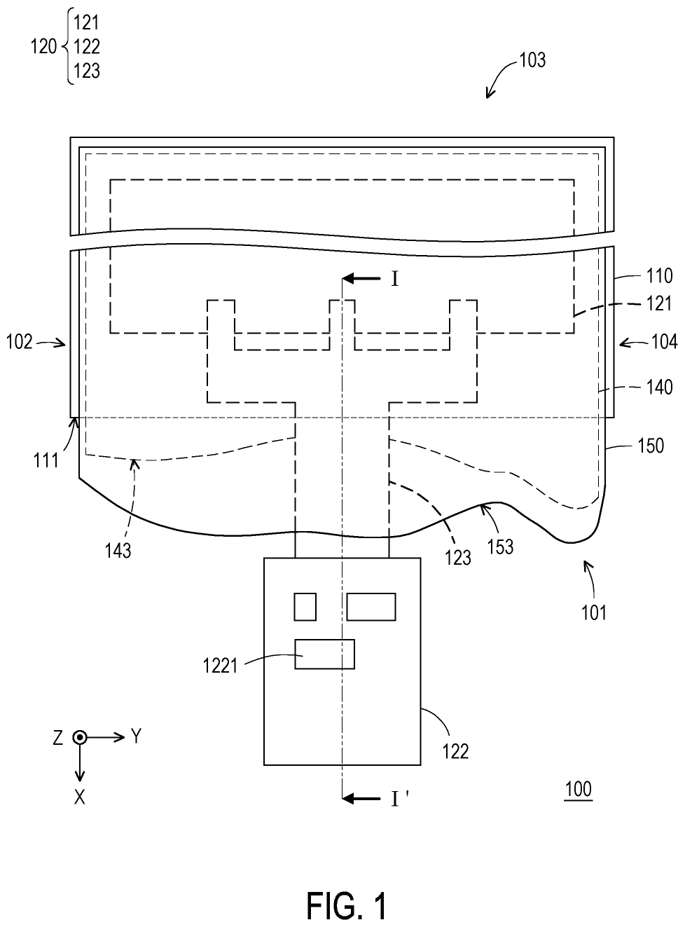

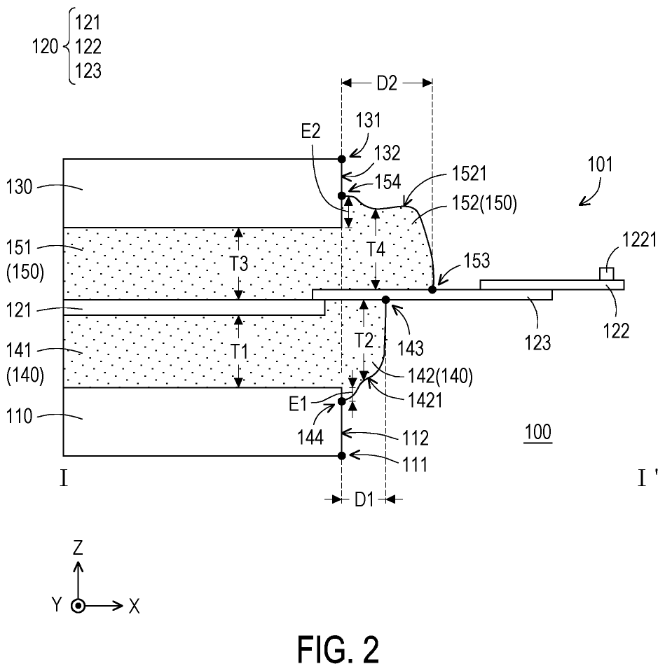

FIG. 1 is a schematic top view of an electronic device according to an embodiment of the disclosure. FIG. 2 is a schematic cross-sectional view of the electronic device of FIG. 1 along section line I-I′. For the clarity of drawings and ease of description, FIG. 1A omits illustration of several elements, for example but not limited to the second substrate 130.

First, with reference to FIG. 1 and FIG. 2, an electronic device 100 of this embodiment has a first side 101, a second side 102, a third side 103, and a fourth side 104. The first side 101 and the third side 103 are opposite to each other, and the second side 102 and the fourth side 104 are opposite to each other. The electronic device 100 includes a first substrate 110, a circuit assembly 120, a second substrate 130, a first adhesive layer 140, and a second adhesive layer 150. The first substrate 110 has a first profile 111, and the first profile 111 corresponds to the first side 101 of the electronic device 100. In this embodiment, a surface of an element may have a profile. For example, in the top view of the electronic device 100 (as shown in FIG. 1), a surface 1521 of the second adhesive layer 150 has a second outer profile 153. Alternatively, a side surface 112 of the first substrate 110 is substantially vertical. The first profile 111 is presented as a line in the top view (as shown in FIG. 1), and the first profile 111 is presented as a dot in the cross-sectional view (as shown in FIG. 2). The first substrate 110 may include a rigid substrate, a flexible substrate, or a combination thereof. For example, the material of the first substrate 110 may include glass, quartz, sapphire, ceramics, polycarbonate (PC), polyimide (PI), polyethylene terephthalate (PET), other suitable substrate materials, or a combination thereof, but not limited thereto.

In this embodiment, a direction X, a direction Y, and a direction Z are different directions. For example, the direction X is an extension direction of section line I-I′, and the direction Z is a normal direction of the electronic device 100. The direction X is substantially perpendicular to the direction Z, and the direction X and the direction Z are each substantially perpendicular to the direction Y, but not limited thereto.

The circuit assembly 120 is disposed on the first substrate 110, and at least a portion of the circuit assembly 120 is outside the first substrate 110. Specifically, the circuit assembly 120 includes a first circuit substrate 121, a second circuit substrate 122, and a third circuit substrate 123. The first circuit substrate 121 is located between the first adhesive layer 140 and the second adhesive layer 150. The third circuit substrate 123 is disposed on the first circuit substrate 121, and the third circuit substrate 123 may extend outward beyond the first substrate 110 at the first side 101. The second circuit substrate 122 is disposed on the third circuit substrate 123 located outside the first substrate 110. The third circuit substrate 123 may connect the first circuit substrate 121 and the second circuit substrate 122. The second circuit substrate 122 may be electrically connected to the first circuit substrate 121 through the third circuit substrate 123, so that a chip 1221 in the second circuit substrate 122 may transmit signals to the first circuit substrate 121.

In this embodiment, the circuit assembly 120 may be, for example but not limited to, a display assembly, a biometric identification assembly, a touch assembly, an antenna assembly, a photochromic assembly, an electrochromic assembly, or a heating assembly. The first circuit substrate 121 may be, for example but not limited to, an active-matrix (AM) driving substrate or a passive-matrix (PM) driving substrate. For example, when the circuit assembly 120 is a display assembly, the first circuit substrate 121 may be a driving substrate of a display, the second circuit substrate 122 may be a printed circuit board (PCB), and the third circuit substrate 123 may be a flexible printed circuit (FPC) board, for example but not limited thereto.

The second substrate 130 is disposed on the circuit assembly 120, so that the circuit assembly 120 is located between the first substrate 110 and the second substrate 130. The second substrate 130 has a second profile 131, and the second profile 131 corresponds to the first side 101 of the electronic device 100. In this embodiment, a side surface 132 of the second substrate 130 is substantially vertical. The second profile 131 is presented as a line in the top view (as shown in FIG. 1), and the second profile 131 is presented as a dot in the cross-sectional view (as shown in FIG. 2). In other words, the first profile 111 and the second profile 131 correspond to the space at the same side (i.e., the first side 101) of the electronic device 100. The second substrate 130 may include a rigid substrate, a flexible substrate, or a combination thereof. The material of the second substrate 130 may be the same as or similar to that of the first substrate 110, and thus will not be repeatedly described.

The first adhesive layer 140 is disposed between the circuit assembly 120 and the first substrate 110. The first adhesive layer 140 may cover the first circuit substrate 121 and part of the third circuit substrate 123 to protect the circuits of the first circuit substrate 121 and the third circuit substrate 123. The material of the first adhesive layer 140 may include polyvinyl butyral (PVB), other suitable adhesive materials, or a combination thereof, but not limited thereto. In this embodiment, the first adhesive layer 140 may include a first portion 141 and a second portion 142 connected to each other. The first portion 141 is disposed within the first substrate 110, and the first portion 141 may be overlapped with the first substrate 110 in the direction Z. At least a portion of the first adhesive layer 140 is outside the first substrate 110. For example, the second portion 142 is disposed outside the first substrate 110. The second portion 142 is disposed at the first side 101 of the electronic device 100, and the second portion 142 may be non-overlapped with the first substrate 110 in the direction Z. In addition, the second portion 142 of the first adhesive layer 140 may also extend in the direction Z to the side surface 112 of the first substrate 110, and the second portion 142 extending to the side surface 112 of the first substrate 110 may have a first extended distance E1. For example, the first extended distance E1 is a thickness of the part of the second portion 142 extending onto the side surface 112 measured along the direction Z.

In this embodiment, the first portion 141 may have a thickness T1 and the second portion 142 may have a thickness T2. For example, the thickness T1 is a thickness of the first portion 141 measured along the direction Z, and the thickness T2 is a thickness of the second portion 142 measured along the direction Z. In this embodiment, the first portion 141 may be divided into three equal parts, and the maximum thickness of the middle part is measured as the thickness T1. The thicknesses of other elements may also be measured similarly. Furthermore, in this embodiment, the second portion 142 has a surface 1421, and the surface 1421 of the second portion 142 of the first adhesive layer 140 has a first outer profile 143 and a first inner profile 144. At least a portion of the first outer profile 143 is outside the first substrate 110, and the first outer profile 143 corresponds to the first side 101 of the electronic device 100. The first outer profile 143 is adjacent to the circuit assembly 120, and the first inner profile 144 is adjacent to the first substrate 110.

The second adhesive layer 150 is disposed between the circuit assembly 120 and the second substrate 130. The second adhesive layer 150 may cover the first circuit substrate 121 and part of the third circuit substrate 123 to protect the circuits of the first circuit substrate 121 and the third circuit substrate 123. The material of the second adhesive layer 150 may be the same as or similar to that of the first adhesive layer 140, and thus will not be repeatedly described. In this embodiment, the second adhesive layer 150 may include a first portion 151 and a second portion 152 connected to each other. The first portion 151 is disposed within the second substrate 130, and the first portion 151 may be overlapped with the second substrate 130 in the direction Z. At least a portion of the second adhesive layer 150 is outside the second substrate 130. For example, the second portion 152 is disposed outside the second substrate 130. The second portion 152 is disposed at the first side 101 of the electronic device 100, and the second portion 152 may be non-overlapped with the second substrate 130 in the direction Z. At least a portion of the first adhesive layer 140 and at least a portion of the second adhesive layer 150 are disposed at the same side of the electronic device 100. In other words, the second portion 142 of the first adhesive layer 140 and the second portion 152 of the second adhesive layer 150 are disposed in the space at the same side (i.e., the first side 101) of the electronic device 100. In addition, the second portion 152 of the second adhesive layer 150 may also extend in the direction Z to the side surface 132 of the second substrate 130, and the second portion 152 extending to the side surface 132 of the second substrate 130 may have a second extended distance E2. For example, the second extended distance E2 is a thickness of the portion of the second portion 152 extending onto the side surface 132 measured along the direction Z. In this embodiment, the first extended distance E1 may be different from the second extended distance E2 to facilitate identification of the correct orientation of the electronic device. For example, a difference between the first extended distance E1 and the second extended distance E2 may be from 0.1 micrometer (μm) to 100 μm, or from 100 μm to 10 millimeters (mm), but not limited thereto. In some embodiments not shown, the second portion of the second adhesive layer may also further extend to an upper surface of the second substrate (i.e., a surface of the second substrate away from the circuit assembly) in addition to the side surface of the second substrate in the direction Z.

In this embodiment, the first portion 151 may have a thickness T3 and the second portion 152 may have a thickness T4. For example, the thickness T3 is a thickness of the first portion 151 measured along the direction Z, and the thickness T4 is a thickness of the second portion 152 measured along the direction Z. Furthermore, in this embodiment, the second portion 152 has the surface 1521, and the surface 1521 of the second portion 152 of the second adhesive layer 150 has the second outer profile 153 and a second inner profile 154. The second outer profile 153 is outside the second substrate 130, and the second outer profile 153 corresponds to the first side 101 of the electronic device 100. The second outer profile 153 is adjacent to the circuit assembly 120, and the second inner profile 154 is adjacent to the second substrate 130. In other words, the first outer profile 143 and the second outer profile 153 correspond to the space at the same side (i.e., the first side 101) of the electronic device 100. In this embodiment, a shape of the first outer profile 143 may be different from a shape of the second outer profile 153, a portion of the first outer profile 143 may be non-overlapped with or separated from a portion of the second outer profile 153 in the direction Z, and the first outer profile 143 may be closer to the first substrate 110 and the second substrate 130 in the direction X than the second outer profile 153 is, but not limited thereto.

In this embodiment, a first distance D1 is between the first profile 111 and the first outer profile 143, and a second distance D2 is between the second profile 131 and the second outer profile 153. For example, the first distance D1 is a distance between the first profile 111 and the first outer profile 143 measured along the direction X, and the second distance D2 is a distance between the second profile 131 and the second outer profile 153 measured along the direction X. In this embodiment, the cross-sectional direction in which the first distance D1 and the second distance D2 are measured may be substantially perpendicular to the first profile 111 and the second profile 131. Any point of the first profile 111 and the second profile 131 may be profiled. In some embodiments, in the top view of the electronic device, the first distance D1 may also be a distance between a point of the first profile 111 and a point of the first outer profile 143 in a direction (e.g., the direction X) perpendicular to the first profile 111. The distances between other elements may also be measured similarly.

In this embodiment, during manufacturing of the first adhesive layer 140 and the second adhesive layer 150, since the amount of a first adhesive material used in the first adhesive layer 140 may be different from the amount of a second adhesive material used in the second adhesive layer 150, or the pressure applied by the first substrate 110 to the first adhesive material may be different from the pressure applied by the second substrate 130 to the second adhesive material, the first outer profile 143 and the second outer profile 153 may be non-overlapped in the direction Z, and the first distance D1 may be different from the second distance D2. In this embodiment, since the first distance D1 may be different from the second distance D2 (or the first outer profile 143 and the second outer profile 153 may be non-overlapped in the direction Z), an operator can easily distinguish the boundary of the first adhesive layer 140 (or the position of the first outer profile 143) and the boundary of the second adhesive layer 150 (or the position of the second outer profile 153) during assembling, which may serve as an inadvertent error prevention design for distinguishing the front and back sides of the electronic device 100 to reduce errors in assembling or improve precision in assembling.

In this embodiment, the first distance D1 may be less than the second distance D2, for example. A difference between the first distance D1 and the second distance D2 may be, for example but not limited to, greater than 0 μm and less than 10 mm (i.e., 0 μm<difference<10 mm), greater than 1 μm and less than 10 mm, or greater than 10 μm and less than 10 mm, to warp the entire structure of the electronic device 100 in advance. In some embodiments, the difference between the first distance D1 and the second distance D2 may be, for example but not limited to, greater than 0 μm and less than 100 μm (i.e., 0 μm<difference<100 μm), greater than 1 μm and less than 100 μm, or greater than 10 μm and less than 100 μm, to keep the overall structure of the electronic device 100 horizontal. In other words, in some embodiments, the first distance may also be substantially equal to or greater than the second distance.

In this embodiment, the thickness T1 of the first portion 141 of the first adhesive layer 140 may be substantially similar to the thickness T3 of the first portion 151 of the second adhesive layer 150, and the thickness T2 of the second portion 142 of the first adhesive layer 140 may be substantially similar to the thickness T4 of the second portion 152 of the second adhesive layer 150, but not limited thereto. In some embodiments, the thickness of the first portion of the first adhesive layer may also be greater or less than the thickness of the first portion of the second adhesive layer. In some embodiments, the thickness of the second portion of the first adhesive layer may also be greater or less than the thickness of the second portion of the second adhesive layer.

In this embodiment, the first substrate 110 has a first refractive index n1, the first adhesive layer 140 has a second refractive index n2, and the first circuit substrate 121 has a third refractive index n3. The first refractive index n1 and the second refractive index n2 may satisfy Formula 1:

$$\frac{\vert n 1 - n 2 \vert}{\vert n 1 + n 2 \vert / 2} < 10 \% ,$$

so that the transmittance of the electronic device 100 may be 90% or more; the second refractive index n2 and the third refractive index n3 may satisfy Formula 2:

$$\frac{\vert n 3 - n 2 \vert}{\vert n 3 + n 2 \vert / 2} < 20 \% ,$$

so that the transmittance of the electronic device 100 may be 90% or more. In some embodiments, the values of the first refractive index n1, the second refractive index n2, and the third refractive index n3 may be respectively obtained from first analyzing the materials of the first substrate 110, the first adhesive layer 140, and the first circuit substrate 121 through a material analyzer, and then from looking up tables (including, but not limited to, research literature, published papers, or textbooks). In some embodiments, when the first circuit substrate includes a plurality of elements, the refractive index of the first circuit substrate may be represented by the refractive index of the base material. For example, when the material of the first substrate 110 includes glass, the material of the first adhesive layer 140 includes PVB, and the material of the first circuit substrate 121 includes PI, substitution of the first refractive index n1 (e.g., 1.50) of glass and the second refractive index n2 (e.g., 1.49) of PVB into Formula 1 may obtain a value (about 0.8%) less than 10%, and substitution of the second refractive index n2 (e.g., 1.49) of PVB and the third refractive index n3 (e.g., 1.64) of PI into Formula 2 may also obtain a value (about 9.7%) less than 20%.

Other embodiments will be provided below for description. It should be noted here that the reference numerals and part of the content of the embodiments above remain to be used in the following embodiments, where the same reference numerals are adopted to refer to the same or similar elements, and the description of the same technical content is omitted. Reference may be made to the embodiments above for the description of the omitted part, which will not be repeated in the following embodiments.

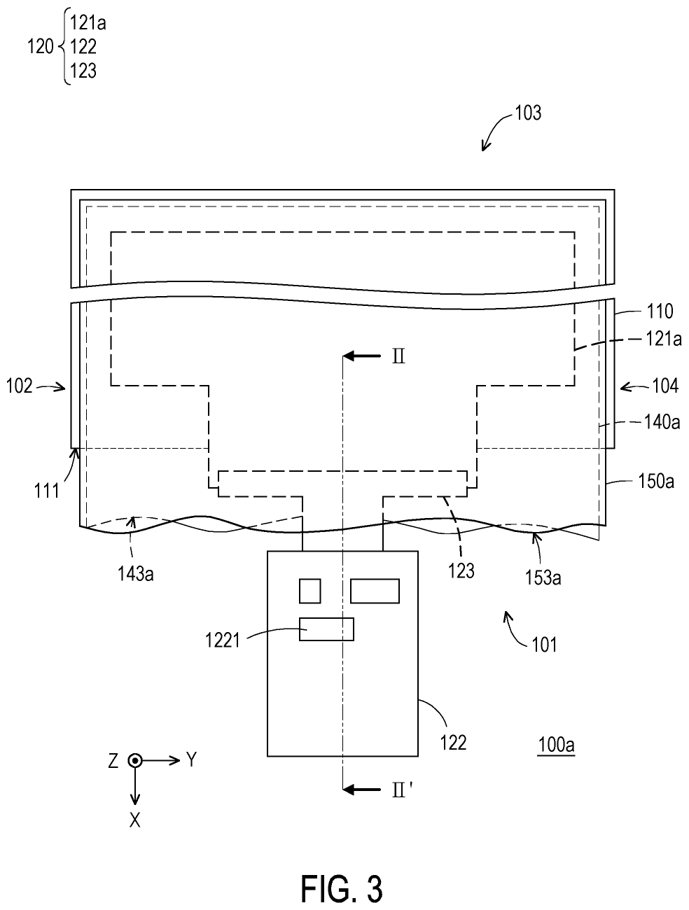

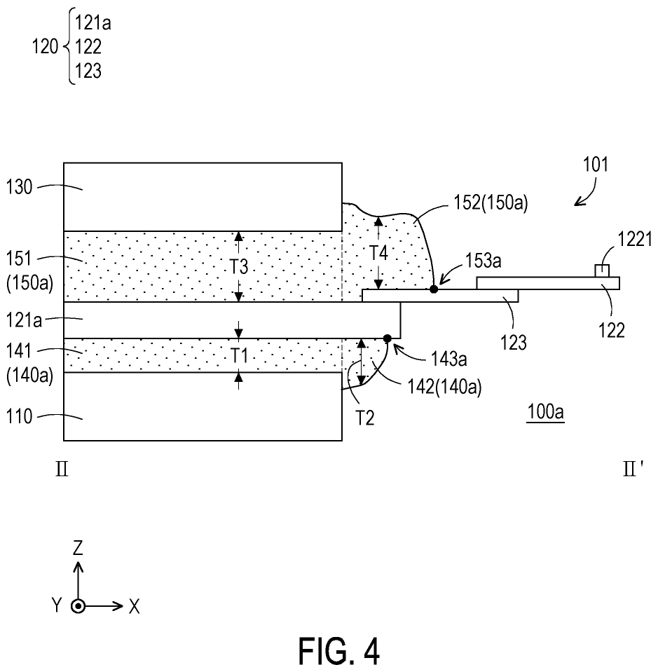

FIG. 3 is a schematic top view of an electronic device according to another embodiment of the disclosure. FIG. 4 is a schematic cross-sectional view of the electronic device of FIG. 3 along section line II-II′. For the clarity of drawings and ease of description, FIG. 3 omits illustration of several elements in an electronic device 100a, for example but not limited to the second substrate 130. With reference to FIG. 1, FIG. 2, FIG. 3, and FIG. 4 together, the electronic device 100a of this embodiment is similar to the electronic device 100 in FIG. 1 and FIG. 2, while the differences between them are that, in the electronic device 100a of this embodiment, part of a first circuit substrate 121a is outside the first substrate 110, and a thickness of a first adhesive layer 140a is different from a thickness of a second adhesive layer 150a.

Specifically, with reference to FIG. 3 and FIG. 4, in the electronic device 100a of this embodiment, the first circuit substrate 121a may extend outward beyond the first substrate 110 at the first side 101.

In this embodiment, the thicknesses T1 and T2 of the first adhesive layer 140a may be different from the thicknesses T3 and T4 of the second adhesive layer 150a. The thickness T1 of the first portion 141 of the first adhesive layer 140a may be less than the thickness T3 of the first portion 151 of the second adhesive layer 150a, and the thickness T2 of the second portion 142 of the first adhesive layer 140a may also be less than the thickness T4 of the second portion 152 of the second adhesive layer 150a, but not limited thereto. In this embodiment, since the thicknesses T1 and T2 of the first adhesive layer 140a may be different from the thicknesses T3 and T4 of the second adhesive layer 150a, an operator can easily distinguish the position of the first adhesive layer 140a and the position of the second adhesive layer 150a during assembling, which may serve as an inadvertent error prevention design for distinguishing the front and back sides of the electronic device 100a to reduce errors in assembling or improve precision in assembling. For example, when a difference between the thickness T1 and the thickness T3 is from 0.1 μm to 50 μm, an operator may identify the position of the electronic device with a testing instrument during assembling. When the difference between the thickness T1 and the thickness T3 is from 0.1 mm to 5 mm, an operator may identify the orientation of the electronic device with the vision thereof during assembling. When a difference between the thickness T2 and the thickness T4 is from 0.1 μm to 100 μm, an operator may identify the position of the electronic device with a testing instrument during assembling. When the difference between the thickness T2 and the thickness T4 is from 0.1 mm to 10 mm, an operator may identify the orientation of the electronic device with the vision thereof during assembling.

In this embodiment, a shape of a first outer profile 143a may be different from a shape of a second outer profile 153a. The first outer profile 143a and the second outer profile 153a may be intersected and partially overlapped with each other in the direction Z. In other words, a portion of the first outer profile 143a and a portion of the second outer profile 153a may be overlapped in the direction Z, and another portion of the first outer profile 143a and another portion of the second outer profile 153a may be non-overlapped in the direction Z.

In this embodiment, the first outer profile 143a may be entirely outside the first substrate 110 and the second outer profile 153a may be entirely outside the second substrate 130, but not limited thereto. In some embodiments not shown, a portion of the first outer profile (or the second outer profile) may be within the first substrate (or the second substrate), so that at least a portion of the first outer profile (or the second outer profile) may be overlapped with the first substrate (or the second substrate) in the direction Z. In some embodiments not shown, a portion of the first outer profile (or the second outer profile) may be within the first substrate (or the second substrate) and another portion of the first outer profile (or the second outer profile) may be outside the first substrate (or the second substrate).

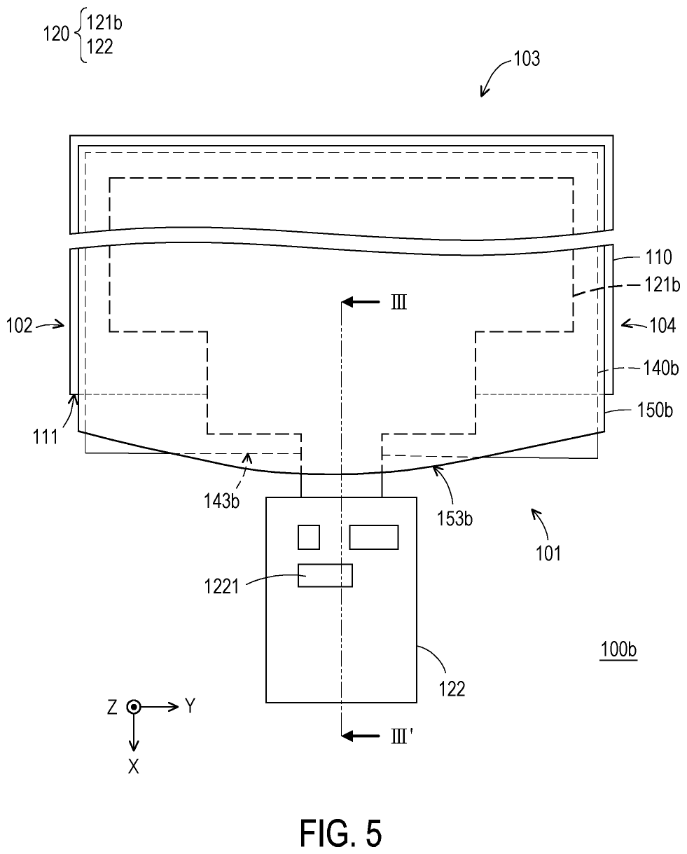

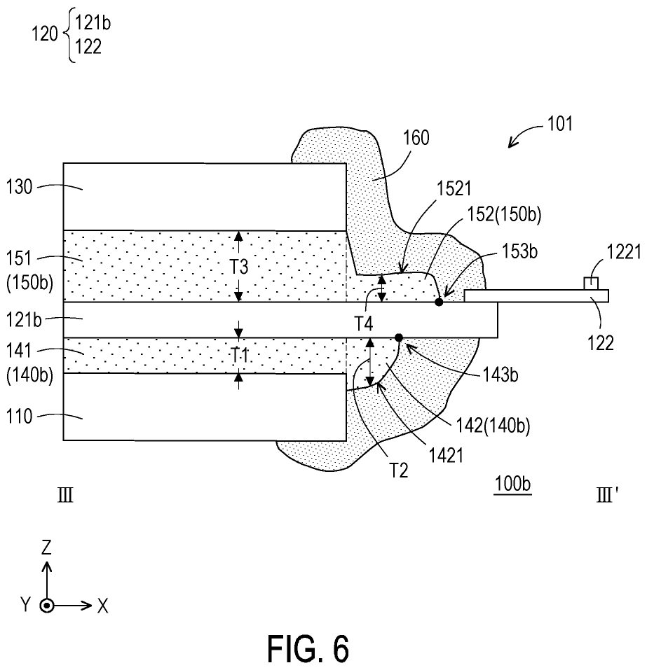

FIG. 5 is a schematic top view of an electronic device according to another embodiment of the disclosure. FIG. 6 is a schematic cross-sectional view of the electronic device of FIG. 5 along section line III-III′. For the clarity of drawings and ease of description, FIG. 5 omits illustration of several elements in an electronic device 100b, for example but not limited to the second substrate 130 and the protective element 160. With reference to FIG. 3, FIG. 4, FIG. 5, and FIG. 6 together, the electronic device 100b of this embodiment is similar to the electronic device 100a in FIG. 3 and FIG. 4, while the differences between them are that, in the electronic device 100b of this embodiment, the arrangement of the third circuit substrate is omitted and part of the second portion 152 of a second adhesive layer 150b is thinned. In addition, the electronic device 100b of this embodiment further includes a protective element 160.

Specifically, with reference to FIG. 5 and FIG. 6, in the electronic device 100b of this embodiment, a first circuit substrate 121b may extend outward beyond the first substrate 110 at the first side 101. The second circuit substrate 122 is disposed on the first circuit substrate 121b. The second circuit substrate 122 may connect the first circuit substrate 121b. The second circuit substrate 122 may be electrically connected to the first circuit substrate 121b.

In this embodiment, a thickness of a first adhesive layer 140b may be different from a thickness of the second adhesive layer 150b. The thickness T1 of the first portion 141 of the first adhesive layer 140b may be less than the thickness T3 of the first portion 151 of the second adhesive layer 150b, and the thickness T2 of the second portion 142 of the first adhesive layer 140b may be greater than the thickness T4 of the second portion 152 of the second adhesive layer 150b. In this embodiment, since the thickness of the first adhesive layer 140b may be different from the thickness of the second adhesive layer 150b, an operator can easily distinguish the position of the first adhesive layer 140b and the position of the second adhesive layer 150b during assembling, which may serve as an inadvertent error prevention design for distinguishing the front and back sides of the electronic device 100b to reduce errors in assembling or improve precision in assembling.

In this embodiment, a shape of a first outer profile 143b may be different from a shape of a second outer profile 153b. The first outer profile 143b and the second outer profile 153b may be intersected and partially overlapped with each other in the direction Z. In other words, a portion of the first outer profile 143b and a portion of the second outer profile 153b may be overlapped in the direction Z, and another portion of the first outer profile 143b and another portion of the second outer profile 153b may be non-overlapped in the direction Z.

In this embodiment, the protective element 160 is disposed on the surface (e.g., the surface 1521 of the second portion 152) of the second adhesive layer 150b and the surface (e.g., the surface 1421 of the second portion 142) of the first adhesive layer 140b, and the protective element 160 may be further disposed on the first outer profile 143b and the second outer profile 153b. The protective element 160 may cover part of the first substrate 110, part of the first circuit substrate 121b, and part of the second substrate 130 to enclose the first adhesive layer 140b and the second adhesive layer 150b to fix the circuit assembly 120, prevent collision, or prevent water. The material of the protective element 160 may include a waterproof adhesive material, a polymer material, or a combination thereof, but not limited thereto. In some embodiments, the material of the protective element 160 may include a metal, an insulating material, plastics, or a combination thereof, but not limited thereto.

In some embodiments not shown, the protective element may also be disposed on the first outer profile alone so as to cover the second portion of the first adhesive layer, part of the first substrate, and part of the first circuit substrate. In some embodiments not shown, the protective element may also be disposed on the second outer profile alone so as to cover the second portion of the second adhesive layer, part of the second substrate, and part of the first circuit substrate.

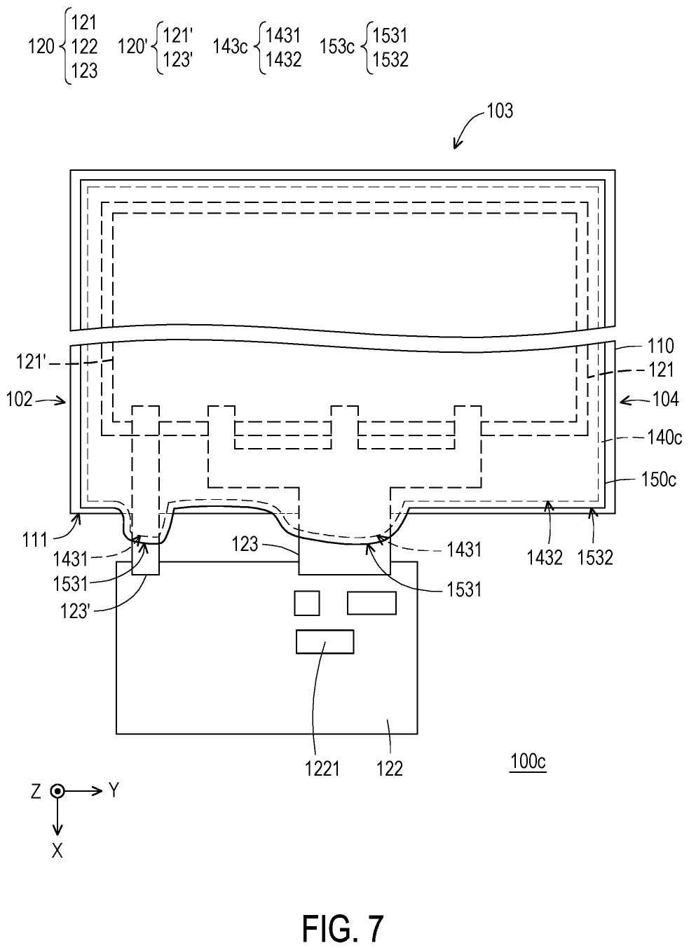

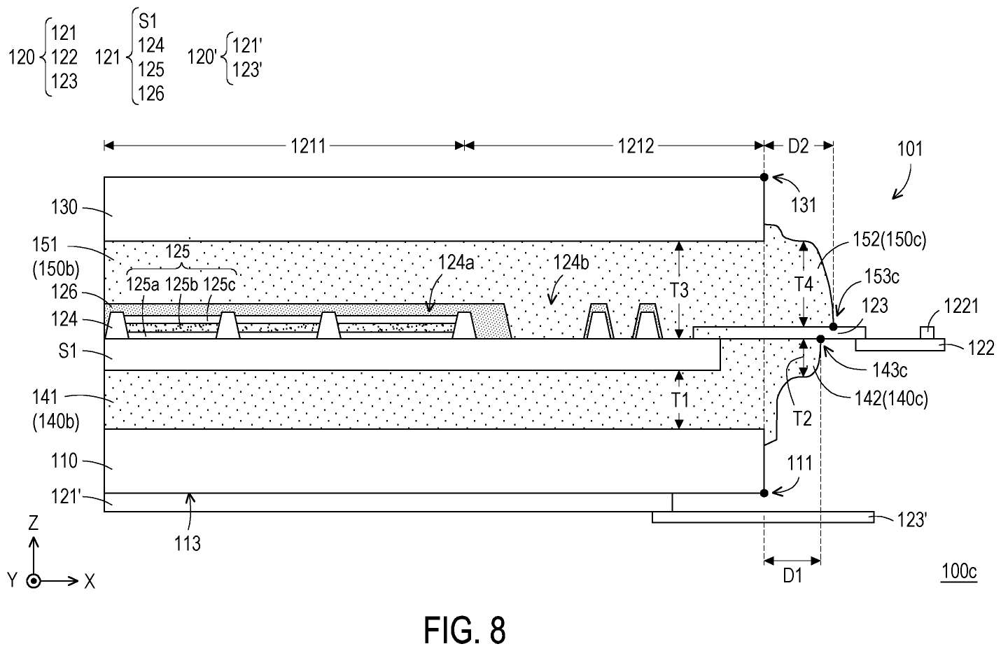

FIG. 7 is a schematic top view of an electronic device according to another embodiment of the disclosure. FIG. 8 is a schematic side view of the electronic device of FIG. 7. For the clarity of drawings and ease of description, FIG. 7 omits illustration of several elements in an electronic device 100c, for example but not limited to the second substrate 130. With reference to FIG. 1, FIG. 2, FIG. 7, and FIG. 8 together, the electronic device 100c of this embodiment is similar to the electronic device 100 in FIG. 1 and FIG. 2, while the differences between them are that, in the electronic device 100c of this embodiment, part of the second portion 142 of a first adhesive layer 140c is thinned, the circuit assembly 120 may be a display assembly, the electronic device 100c further includes a circuit assembly 120′, and the circuit assembly 120′ may be a touch assembly.

Specifically, with reference to FIG. 7 and FIG. 8, in the electronic device 100c of this embodiment, the first circuit substrate 121 includes a base material S1, a pixel define layer (PDL) 124, an organic light-emitting diode (OLED) 125, and an insulating layer 126. The first circuit substrate 121 has a display region 1211 and a non-display region 1212. The PDL 124 is disposed in the display region 1211 and the non-display region 1212 on the first circuit substrate 121. The PDL 124 has an opening 124a located in the display region 1211 and an opening 124b located in the non-display region 1212. The OLED 125 is disposed on the first circuit substrate 121 and disposed in the opening 124a of the PDL 124. The OLED 125 includes a first conductive layer 125a, a light-emitting layer 125b, and a second conductive layer 125c. The light-emitting layer 125b is disposed between the first conductive layer 125a and the second conductive layer 125c. The insulating layer 126 is disposed on the first circuit substrate 121 to cover the PDL 124 and the OLED 125.

The circuit assembly 120′ is disposed on a surface 113 of the first substrate 110 away from the first adhesive layer 140c. The circuit assembly 120′ includes a first circuit substrate 121′ and a third circuit substrate 123′. The first circuit substrate 121′ is disposed on the surface 113 of the first substrate 110. The third circuit substrate 123′ is disposed on the first circuit substrate 121′, and the third circuit substrate 123′ may extend outward beyond the first substrate 110 at the first side 101. The third circuit substrate 123′ may be electrically connected to the first circuit substrate 121′. The third circuit substrate 123′ may also be electrically connected to the second circuit substrate 122, so that the chip 1221 in the second circuit substrate 122 may transmit signals to the first circuit substrate 121′ through the third circuit substrate 123′.

In this embodiment, a thickness of the first adhesive layer 140c may be different from a thickness of a second adhesive layer 150c. The thickness T1 of the first portion 141 of the first adhesive layer 140c may be less than the thickness T3 of the first portion 151 of the second adhesive layer 150c, and the thickness T2 of the second portion 142 of the first adhesive layer 140c may also be less than the thickness T4 of the second portion 152 of the second adhesive layer 150c. In this embodiment, since the thickness of the first adhesive layer 140c may be different from the thickness of the second adhesive layer 150c, an operator can easily distinguish the position of the first adhesive layer 140c and the position of the second adhesive layer 150c during assembling, which may serve as an inadvertent error prevention design for distinguishing the front and back sides of the electronic device 100c to reduce errors in assembling or improve precision in assembling.

In this embodiment, the third circuit substrate 123 or the third circuit substrate 123′ may be easily bent to a side of the first substrate 110 since part of the second portion 142 of the first adhesive layer 140c is thinned.

In this embodiment, the first distance D1 between the first profile 111 and a first outer profile 143c may be substantially equal to the second distance D2 between the second profile 131 and a second outer profile 153c, but not limited thereto.

In this embodiment, a shape of the first outer profile 143c may be substantially similar to a shape of the second outer profile 153c. The first outer profile 143c and the second outer profile 153c may be overlapped in the direction Z. A portion 1431 of the first outer profile 143c is outside the first substrate 110 and another portion 1432 of the first outer profile 143c is within the first substrate 110. A portion 1531 of the second outer profile 153c is outside the second substrate 130 and another portion 1532 of the second outer profile 153c is within the second substrate 130. The portion 1431 of the first outer profile 143c and the portion 1531 of the second outer profile 153c may be disposed corresponding to the third circuit substrate 123 and the third circuit substrate 123′. The another portion 1432 of the first outer profile 143c may be overlapped with the first substrate 110 in the direction Z (i.e., a normal direction of the electronic device 100c), and the another portion 1532 of the second outer profile 153c may be overlapped with the second substrate 130 in the direction Z (i.e., the normal direction of the electronic device 100c). In addition, the second portion 142 of the first adhesive layer 140c and the second portion 152 of the second adhesive layer 150c may cover part of the third circuit substrate 123 and part of the third circuit substrate 123′ to protect the circuits of the third circuit substrate 123 and the third circuit substrate 123′.

In some embodiments not shown, the base material of the first circuit substrate may have a hole located in the display region, and the PDL may further have another opening disposed corresponding to the hole. The hole may or may not expose the first adhesive layer, and the second adhesive layer may also be disposed in the another opening of the PDL, the hole of the base material, and part of the opening of the PDL.

In some embodiments not shown, the first circuit substrate further includes a filling layer, the base material of the first circuit substrate has a hole located in the display region, and the PDL may further have another opening disposed corresponding to the hole. The filling layer may be disposed in the another opening of the PDL, the hole of the base material, and part of the opening of the PDL.

Although the circuit assembly of this embodiment is an LED display assembly, and an OLED is taken as the light-emitting element, the disclosure does not limit the types of the display assembly and the light-emitting element. In other words, in some embodiments not shown, the circuit assembly may also be a liquid crystal display assembly (including a color filter layer, a liquid crystal layer, and a backlight module). In some embodiments, the light-emitting element in the LED display assembly may also be an inorganic LED (including a mini LED, a micro LED, or a quantum dot LED).

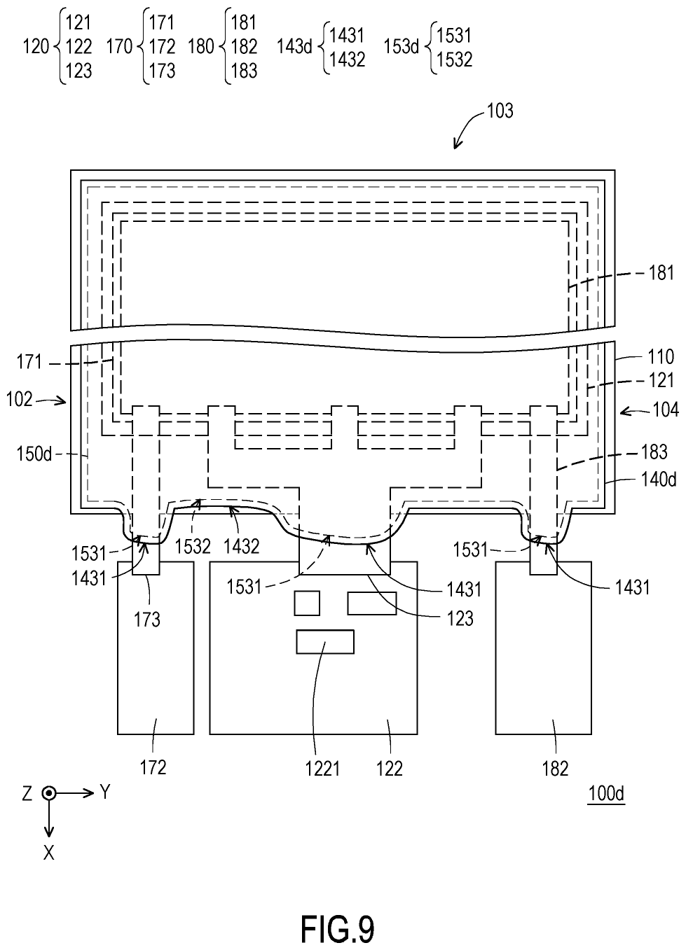

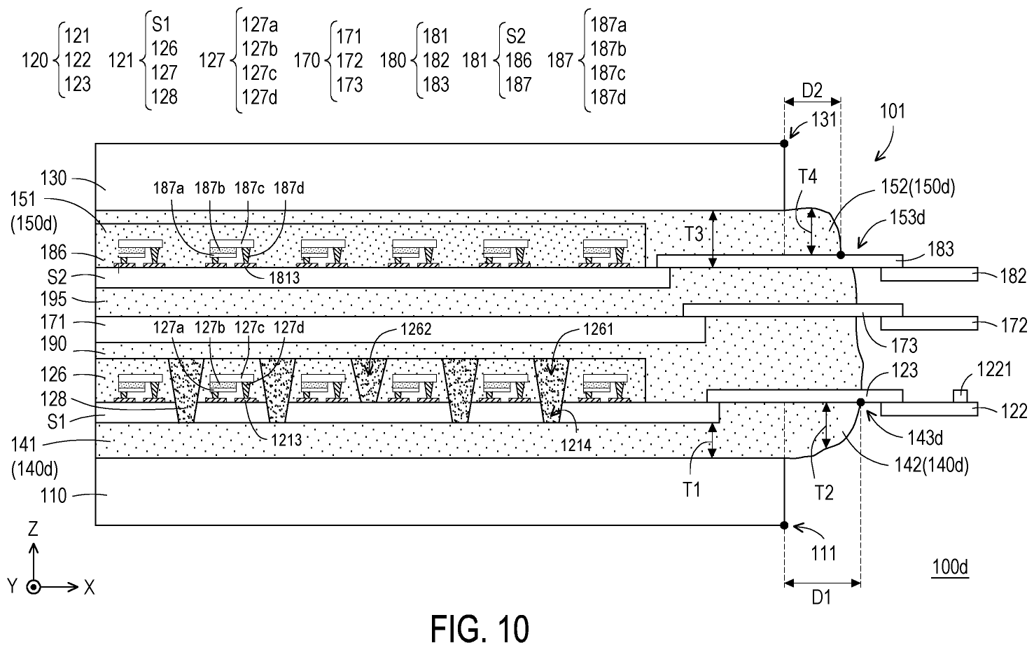

FIG. 9 is a schematic top view of an electronic device according to another embodiment of the disclosure. FIG. 10 is a schematic side view of the electronic device of FIG. 9. For the clarity of drawings and ease of description, FIG. 9 omits illustration of several elements in an electronic device 100d, for example but not limited to the second substrate 130. With reference to FIG. 1, FIG. 2, FIG. 9, and FIG. 10 together, the electronic device 100d of this embodiment is similar to the electronic device 100 in FIG. 1 and FIG. 2, while the differences between them are that, the electronic device 100d of this embodiment further includes a circuit assembly 170, a circuit assembly 180, a third adhesive layer 190, and a fourth adhesive layer 195. The circuit assembly 120 and the circuit assembly 180 may be display assemblies, and the circuit assembly 170 may be an electrochromic assembly.

Specifically, with reference to FIG. 9 and FIG. 10, in the electronic device 100d of this embodiment, the first circuit substrate 121 includes the base material S1, the insulating layer 126, an inorganic light-emitting diode (LED) 127, and a filling layer 128. The first circuit substrate 121 has bonding pads 1213, a circuit layer (not shown) located between the bonding pads 1213 and the base material S1, and a hole 1214 of the base material S1. The inorganic LED 127 is disposed on the base material S1. The inorganic LED 127 includes a first semiconductor layer 127a, a light-emitting layer 127b, a second semiconductor layer 127c, and connection pads 127d. The light-emitting layer 127b is disposed between the first semiconductor layer 127a and the second semiconductor layer 127c. The connection pads 127d are disposed on the first semiconductor layer 127a and the second semiconductor layer 127c. The inorganic LED 127 may be bonded through the connection pads 127d to the bonding pads 1213. The insulating layer 126 is disposed on the base material S1 to cover the inorganic LED 127. The insulating layer 126 has an opening 1261 disposed corresponding to the hole 1214 and an opening 1262. The filling layer 128 is disposed in the opening 1261, the hole 1214, and the opening 1262.

The third adhesive layer 190 is disposed on the circuit assembly 120. The circuit assembly 170 is disposed on the third adhesive layer 190. The circuit assembly 170 includes a first circuit substrate 171, a second circuit substrate 172, and a third circuit substrate 173. The third circuit substrate 173 is disposed on the first circuit substrate 171, and the third circuit substrate 173 may extend outward beyond the first substrate 110 at the first side 101. The second circuit substrate 172 is disposed on the third circuit substrate 173 located outside the first substrate 110. The third circuit substrate 173 may connect the first circuit substrate 171 and the second circuit substrate 172. The second circuit substrate 172 may be electrically connected to the first circuit substrate 171 through the third circuit substrate 173. The circuit assembly 170 may further include dyes to adjust the transparency of the circuit assembly 170.

The fourth adhesive layer 195 is disposed on the circuit assembly 170. The circuit assembly 180 is disposed on the fourth adhesive layer 195. The circuit assembly 180 includes a first circuit substrate 181, a second circuit substrate 182, and a third circuit substrate 183. The first circuit substrate 181 includes a base material S2, an insulating layer 186, and an inorganic light-emitting diode (LED) 187. The third circuit substrate 183 is disposed on the first circuit substrate 181, and the third circuit substrate 183 may extend outward beyond the first substrate 110 at the first side 101. The second circuit substrate 182 is disposed on the third circuit substrate 183 and located outside the first substrate 110. The third circuit substrate 183 may connect the first circuit substrate 181 and the second circuit substrate 182. The second circuit substrate 182 may be electrically connected to the first circuit substrate 181 through the third circuit substrate 183. The first circuit substrate 181 has bonding pads 1813 and a circuit layer (not shown) located between the bonding pads 1813 and the base material S2. The inorganic LED 187 is disposed on the base material S2. The inorganic LED 187 includes a first semiconductor layer 187a, a light-emitting layer 187b, a second semiconductor layer 187c, and connection pads 187d. The light-emitting layer 187b is disposed between the first semiconductor layer 187a and the second semiconductor layer 187c. The connection pads 187d are disposed on the first semiconductor layer 187a and the second semiconductor layer 187c. The inorganic LED 187 may be bonded through the connection pads 187d to the bonding pads 1813 of the first circuit substrate 181. The insulating layer 186 is disposed on the base material S2 to cover the inorganic LED 187.

In this embodiment, a thickness of a first adhesive layer 140d may be different from a thickness of a second adhesive layer 150d. The thickness T1 of the first portion 141 of the first adhesive layer 140d may be less than the thickness T3 of the first portion 151 of the second adhesive layer 150d, and the thickness T2 of the second portion 142 of the first adhesive layer 140d may be substantially equal to the thickness T4 of the second portion 152 of the second adhesive layer 150d. In this embodiment, since the thickness of the first adhesive layer 140d may be different from the thickness of the second adhesive layer 150d, an operator can easily distinguish the position of the first adhesive layer 140d and the position of the second adhesive layer 150d during assembling, which may serve as an inadvertent error prevention design for distinguishing the front and back sides of the electronic device 100d to reduce errors in assembling or improve precision in assembling.

In this embodiment, the first distance D1 between the first profile 111 and a first outer profile 143d may be substantially equal to the second distance D2 between the second profile 131 and a second outer profile 153d, but not limited thereto.

In this embodiment, a shape of the first outer profile 143d may be substantially similar to a shape of the second outer profile 153d. The portion 1431 of the first outer profile 143d is outside the first substrate 110 and the another portion 1432 of the first outer profile 143d is within the first substrate 110. The portion 1531 of the second outer profile 153d is outside the second substrate 130 and the another portion 1532 of the second outer profile 153d is within the second substrate 130. The portion 1431 of the first outer profile 143d and the portion 1531 of the second outer profile 153d may correspond to the third circuit substrate 123, the third circuit substrate 173, and the third circuit substrate 183. The another portion 1432 of the first outer profile 143d may be overlapped with the first substrate 110 in the direction Z (i.e., a normal direction of the electronic device 100d), and the another portion 1532 of the second outer profile 153d may be overlapped with the second substrate 130 in the direction Z (i.e., the normal direction of the electronic device 100d). In addition, the second portion 142 of the first adhesive layer 140d and the second portion 152 of the second adhesive layer 150d may cover part of the third circuit substrate 123 and part of the third circuit substrate 183 to protect the circuits of the third circuit substrate 123 and the third circuit substrate 183.

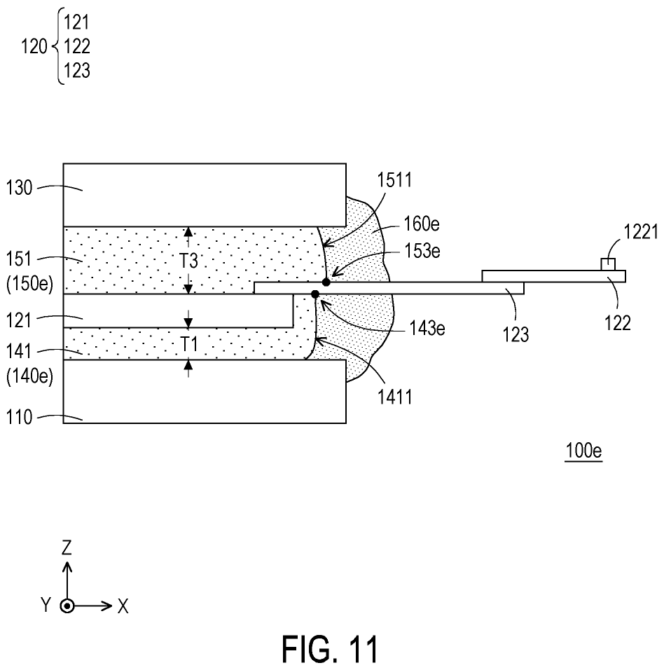

FIG. 11 is a schematic cross-sectional view of an electronic device according to another embodiment of the disclosure. With reference to FIG. 6 and FIG. 11 together, an electronic device 100e of this embodiment is similar to the electronic device 100b of FIG. 6, while the differences between them are that a first adhesive layer 140e does not extend beyond the first substrate 110 and a second adhesive layer 150e does not extend beyond the second substrate 130. In other words, in the direction Z, the first adhesive layer 140e is recessed within the first substrate 110 and the second adhesive layer 150e is also recessed within the second substrate 130.

With reference to FIG. 11, in the electronic device 100e of this embodiment, the first adhesive layer 140e is disposed within the first substrate 110 and the second adhesive layer 150e is disposed within the second substrate 130. A first outer profile 143e is within the first substrate 110 and a second outer profile 153e is within the second substrate 130, so that the first outer profile 143e may be overlapped with the first substrate 110 in the direction Z (i.e., a normal direction of the electronic device 100e), and the second outer profile 153e may be overlapped with the second substrate 130 in the direction Z (i.e., the normal direction of the electronic device 100e).

In this embodiment, a thickness of the first adhesive layer 140e may be different from a thickness of the second adhesive layer 150e. The thickness T1 of the first portion 141 of the first adhesive layer 140e may be less than the thickness T3 of the first portion 151 of the second adhesive layer 150e. In this embodiment, since the thickness of the first adhesive layer 140e may be different from the thickness of the second adhesive layer 150e, an operator can easily distinguish the position of the first adhesive layer 140e and the position of the second adhesive layer 150e during assembling, which may serve as an inadvertent error prevention design for distinguishing the front and back sides of the electronic device 100e to reduce errors in assembling or improve precision in assembling.

In this embodiment, a protective element 160e is disposed on a surface (e.g., a surface 1511 of the first portion 151) of the second adhesive layer 150e and a surface (e.g., a surface 1411 of the first portion 141) of the first adhesive layer 140e, and the protective element 160e may be further disposed on the first outer profile 143e and the second outer profile 153e. The protective element 160e may cover part of the first substrate 110, the first portion 141 of the first adhesive layer 140e, part of the third circuit substrate 123, the first portion 151 of the second adhesive layer 150e, and part of the second substrate 130 to enclose the first adhesive layer 140e and the second adhesive layer 150e to fix the circuit assembly 120, prevent collision, or prevent water.

In this embodiment, although the protective element may be configured to enclose the first adhesive layer recessed within the first substrate and the second adhesive layer recessed within the second substrate, the disclosure does not limit the aspects of the first adhesive layer and the second adhesive layer that may be enclosed by the protective element as long as the protective element may enclose the first adhesive layer and the second adhesive layer. In other words, in some embodiments, the protective element may also be configured to enclose the first adhesive layer protruding from the first substrate. In some embodiments, the protective element may also be configured to enclose the second adhesive layer protruding from the second substrate.

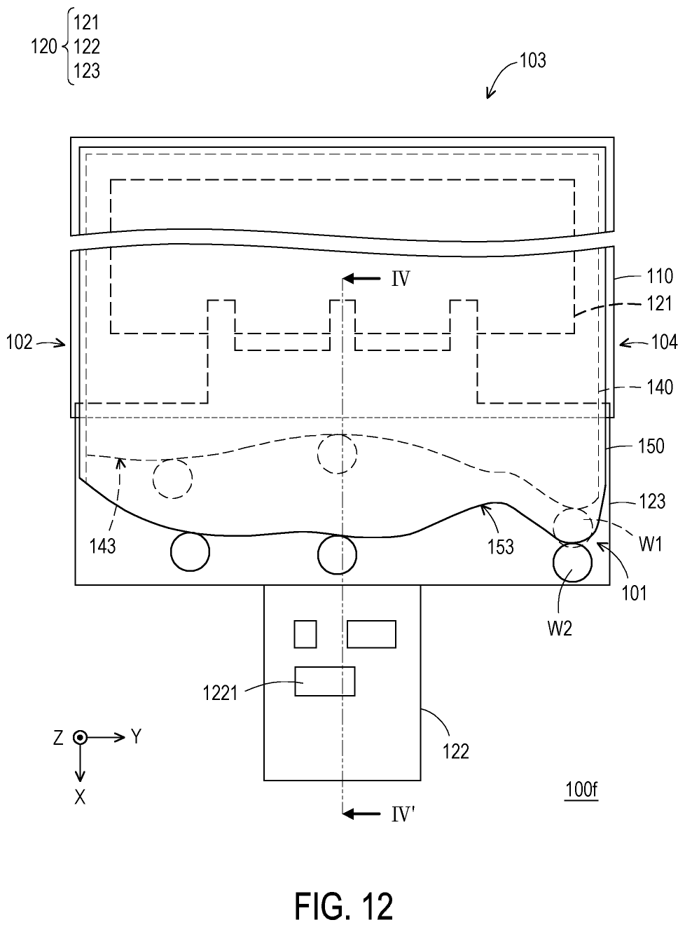

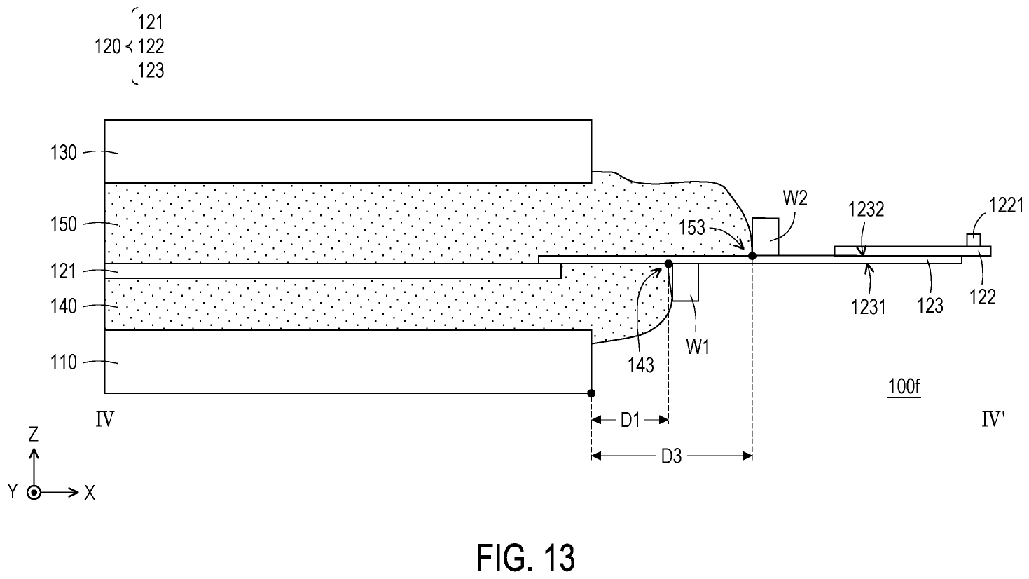

FIG. 12 is a schematic top view of an electronic device according to another embodiment of the disclosure. FIG. 13 is a schematic cross-sectional view of the electronic device of FIG. 12 along section line IV-IV′. For the clarity of drawings and ease of description, FIG. 12 omits illustration of several elements in an electronic device 100f. With reference to FIG. 1, FIG. 2, FIG. 12, and FIG. 13 together, the electronic device 100f of this embodiment is similar to the electronic device 100 in FIG. 1 and FIG. 2, while the differences between them are that the electronic device 100f of this embodiment may include a plurality of first blocking walls W1 and a plurality of second blocking walls W2 (three first blocking walls W1 and three second blocking walls W2 are schematically taken as an example in FIG. 12, but not limited thereto).

With reference to FIG. 12 and FIG. 13, in the electronic device 100f of this embodiment, the third circuit substrate 123 has a surface 1231 and a surface 1232 opposite to each other. The surface 1231 faces the first adhesive layer 140 and the surface 1232 faces the second adhesive layer 150.

In this embodiment, the first blocking walls W1 are disposed on the surface 1231, so that the first adhesive layer 140 does not extend outward beyond the first blocking walls W1 during manufacturing. The second blocking walls W2 are disposed on the surface 1232, so that the second adhesive layer 150 does not extend outward beyond the second blocking walls W2 during manufacturing. Since the second blocking walls W2 are farther away from the first substrate 110 in the direction X than the first blocking walls W1 are, a third distance D3 between the first profile 111 and the second outer profile 153 may be greater than the first distance D1 between the first profile 111 and the first outer profile 143.

In this embodiment, the materials of the first blocking walls W1 and the second blocking walls W2 may include metals, insulating materials, or a combination thereof, but not limited thereto.

In the top view of the electronic device 100f of this embodiment, although the first blocking walls (or the second blocking walls) are disposed in the fashion of a plurality of single dots at specific positions along a predetermined first outer profile (or second outer profile), the disclosure does not limit the form of the first blocking walls (or the second blocking walls) as long as the first blocking walls (or the second blocking walls) may be configured so that the first adhesive layer (or the second adhesive layer) does not go over the position of the predetermined first outer profile (or second outer profile). In other words, in some embodiments not shown, the first blocking walls (or second blocking walls) may also be disposed in the form of a continuous line along the predetermined first outer profile (or second outer profile).

In summary of the foregoing, in the electronic device according to the embodiments of the disclosure, since the first distance may be different from the second distance (or the first outer profile and the second outer profile may be non-overlapped in the direction Z), an operator can easily distinguish the boundary of the first adhesive layer (or the position of the first outer profile) and the boundary of the second adhesive layer (or the position of the second outer profile) during assembling, which may serve as an inadvertent error prevention design for distinguishing the front and back sides of the electronic device to reduce errors in assembling or improve precision in assembling. In addition, in this embodiment, since the thickness of the first adhesive layer may be different from the thickness of the second adhesive layer, an operator can easily distinguish the position of the first adhesive layer and the position of the second adhesive layer during assembling, which may serve as an inadvertent error prevention design for distinguishing the front and back sides of the electronic device to reduce errors in assembling or improve precision in assembling.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device comprising:
a first substrate;
a circuit assembly disposed on the first substrate;
a second substrate disposed on the circuit assembly;
a first adhesive layer disposed between the circuit assembly and the first substrate, the first adhesive layer having a first outer profile; and
a second adhesive layer disposed between the circuit assembly and the second substrate, the second adhesive layer having a second outer profile, wherein
the first outer profile and the second outer profile correspond to a same side of the electronic device, and at least a portion of the first outer profile and at least a portion of the second outer profile are non-overlapped.

2. The electronic device according to claim 1, wherein the first substrate has a first profile, the second substrate has a second profile, the first profile and the second profile correspond to a same side of the electronic device, and a first distance between the first profile and the first outer profile is different from a second distance between the second profile and the second outer profile.

3. The electronic device according to claim 2, wherein a difference between the first distance and the second distance is greater than 0 micrometer and less than 10 millimeters.

4. The electronic device according to claim 3, wherein the difference between the first distance and the second distance is greater than 0 micrometer and less than 100 micrometers.

5. The electronic device according to claim 1, wherein the at least a portion of the first outer profile is outside the first substrate.

6. The electronic device according to claim 1, wherein the at least a portion of the first outer profile is overlapped with the first substrate in a normal direction of the electronic device.

7. The electronic device according to claim 1, wherein at least a portion of the first adhesive layer is outside the first substrate, at least a portion of the second adhesive layer is outside the second substrate, the at least a portion of the first adhesive layer and the at least a portion of the second adhesive layer are disposed at a same side of the electronic device, and a first thickness of the at least a portion of the first adhesive layer is different from a second thickness of the at least a portion of the second adhesive layer.

8. The electronic device according to claim 7, wherein a difference between the first thickness and the second thickness is from 0.1 millimeter to 10 millimeters.

9. The electronic device according to claim 7, wherein a difference between the first thickness and the second thickness is from 0.1 micrometer to 100 micrometers.

10. The electronic device according to claim 7, wherein the at least a portion of the first adhesive layer extends to a side surface of the first substrate and has a first extended distance, the at least a portion of the second adhesive layer extends to a side surface of the second substrate and has a second extended distance, and the first extended distance of the first adhesive layer is different from the second extended distance of the second adhesive layer.

11. The electronic device according to claim 10, wherein a difference between the first extended distance and the second extended distance is from 100 micrometers to 10 millimeters.

12. The electronic device according to claim 11, wherein the difference between the first extended distance and the second extended distance is from 0.1 micrometer to 100 micrometers.

13. The electronic device according to claim 1, further comprising:
a protective element disposed on at least one of the first outer profile and the second outer profile.

14. The electronic device according to claim 1, wherein the circuit assembly comprises a first circuit substrate and a second circuit substrate, the first circuit substrate is located between the first adhesive layer and the second adhesive layer, and the second circuit substrate is electrically connected to the first circuit substrate.

15. The electronic device according to claim 1, wherein at least a portion of the circuit assembly is outside the first substrate.

16. The electronic device according to claim 1, comprising a transparent display device, a transparency adjustment device, an antenna device, a sensing device, or a heating device.

17. The electronic device according to claim 1, wherein the first substrate has a first refractive index n1, the first adhesive layer has a second refractive index n2, and the first refractive index n1 and the second refractive index n2 satisfy:
$$\frac{\vert n 1 - n 2 \vert}{\vert n 1 + n 2 \vert / 2} < 10 \% .$$

18. The electronic device according to claim 17, wherein the circuit assembly comprises a first circuit substrate, the first circuit substrate is disposed between the first adhesive layer and the second adhesive layer, the first circuit substrate has a third refractive index n3, and the second refractive index n2 and the third refractive index n3 satisfy:
$$\frac{\vert n 3 - n 2 \vert}{\vert n 3 + n 2 \vert / 2} < 20 \% .$$

19. The electronic device according to claim 1, wherein a shape of the first outer profile is different from a shape of the second outer profile.

20. The electronic device according to claim 1, wherein the first outer profile is within the first substrate.
